(19) United States
(12) Patent Application Publication
(10) Pub. No.: US 2018/0323351 A1
(43) Pub. Date: Nov. 8, 2018

(54) LIGHT-EMITTING DIODE MODULE FOR PLANT GROWTH

(71) Applicant: SOLIDLITE CORP., Hsinchu County (TW)

(72) Inventors: HSING CHEN, HSINCHU COUNTY (TW); PIN-HSIN KUO, HSINCHU COUNTY (TW); WEI-HAO CHEN, HSINCHU COUNTY (TW)

(21) Appl. No.: 15/906,364

(22) Filed: Feb. 27, 2018

(30) Foreign Application Priority Data
May 3, 2017 (TW) 106114878

(51) Int. Cl. H01L 33/50; H01L 33/56; A01G 7/04

(52) U.S. Cl. CPC H01L 33/504; A01G 7/045; H01L 33/56; H01L 33/507

(57) ABSTRACT

The present disclosure illustrates a light-emitting diode module for plant growth. There are at least two LED chips in different wavelengths packaged with phosphor powder in certain wavelengths: a blue light LED chip (wavelength from 425 nm to 435 nm) covered by a silicone resin with red phosphor powder can emit a red light in a wavelength from 620 nm to 730 nm when being stimulated; another blue light LED chip (wavelength from 445 nm to 455 nm) covered by silicone resin with chartreuse phosphor powder mixture can emit a chartreuse light in a wavelength from 515 nm to 560 nm when being stimulated. The composite light spectrum generated from above LED chips and different types of the phosphor powder is close to the McCree photosynthesis spectrum, and it is an optimal spectrum for plant growth of the present disclosure.

### BACKGROUND

### a) Technical Field

The present disclosure relates to optoelectronic technology and agricultural technology, particularly a light-emitting diode (LED) module for plant growth, where a light-emitting element is packaged by combining at least two kinds of LED chips in different wavelengths, along with phosphor powder in specific wavelengths.

### b) Description of the Related Art

In recent years, the artificial light sources have been widely used in forcing culture and flowering regulation on crops. The LED light for plant growth are advantageous in energy saving and low heat generation, and makes them become the trend of future agriculture. According to plant types and statuses, there are different requirements for light intensity, light spectrum and photoperiod, wherein plants are most obviously affected by photosynthesis. According to the research of photosynthesis efficiency of different light sources from US and Japan, the optimal energy spectrum curve is the McCree photosynthesis curve, as shown in FIG. 1. Therefore, the more similar to the light spectrum shown in FIG. 1, the more photosynthesis efficiency it can be.

The photosynthesis is an important photochemical reaction within plants that convert light energy into chemical energy, wherein the light is necessary for stimulating those biochemical reactions for normal growing of plants. Chlorophylls are green pigments inside plants, especially distribute in leaves and stems. There are two kinds of chlorophyll: chlorophyll a and chlorophyll b. Chlorophyll a, the primary pigment to conduct light reaction in photosynthesis, is responsible for light capturing and charge separation. It is the center of light reaction in photosynthesis. Chlorophyll b and other pigments (carotene and xanthophyll) are only responsible for light capturing. Chlorophyll b, carotene and xanthophyll are also called the co-pigments. The absorbed light energy from them will be transferred to chlorophyll a to conduct the light reaction.

The absorbance spectra of chlorophyll a and chlorophyll b are shown in FIG. 2. For chlorophyll a, absorbed peaks are observed on 430 nm (blue light) and 662 nm (red light) respectively. On the other hand, absorbed peaks are observed on 454 nm (blue light) and 643 nm (red light) for chlorophyll b. There are some absorbance on 500-540 nm (green light) for chlorophyll b as well.

In order to make artificial light spectra fit to the absorbance spectra of chlorophyll a and chlorophyll b, a first kind of artificial light sold on the current market is made by yellow phosphor powder which is stimulated by a blue light LED chip (460 nm), along with a single red light LED chip (660 nm). Its spectrum is shown in FIG. 3. However, its shortcoming is that there is no absorbed peak on 430 nm for chlorophyll a, which reduces the efficiency in light capturing. Therefore, when plants grow under such kind of artificial light source, light energy capturing can only be done by chlorophyll b and co-pigments, and the light energy is hereafter transmitted to the reaction center of photosynthesis, i.e., chlorophyll a. Such kind of pathway has less efficiency on photosynthesis and plant growth, which result in abnormal shape and thin leaves as well.

There are many stages of plants' life cycle, such as sprouting, branching and blooming. Each stage from abovementioned requires the stimulation of red light wavelength over 700 nm (such as 730 nm) as a signal to trigger all kinds of important transformation, so that the plant can grow normally. For example, when the seeds of tobacco, lettuce, and foxglove are stimulated by light, they can get the ability to sprout or speed up sprouting. The seedlings of most plants need to be stimulated by light, so that they can turn green and grow normally. The stems of the growing plants will stretch out to light. The abovementioned transformation stimulated by infrared (>700 nm) is so called photomorphogenesis.

On the other hand, a second kind of artificial light sold on the market is made by combining a red light LED chip with a blue light LED chip (the combination ratio is 8:2 or 9:1) for plant growth. The spectrum is shown in FIG. 4. Both the first kind of artificial light and the second kind of artificial light lack of the wavelength over 700 nm (such as 730 nm). Therefore, plants grown under these kinds of light cannot complete photomorphogenesis normally.

During the growth of plants, leaves on lower layer will be shaded by upper ones, and therefore only the chartreuse light (500-560 nm) can penetrate the upper-layer leaves and reach the surface of lower-layer leaves. The chartreuse light is also considered to stimulate biosynthesis of carotene in recent year. After capturing the green light (500-540 nm) by chlorophyll b, the light energy will be transmitted to the reaction center of photosynthesis, i.e., chlorophyll a, to conduct the subsequent light reaction and improve the efficiency of photosynthesis. Accordingly, the leaves will be strong and taste crispy.

The other shortcoming in the abovementioned second kind of artificial light sold on the market is that this kind of LED light spectrum content only one narrow blue light waveband and one narrow red light waveband. For example, the peak FWHM (Full Width at Half Maximum) for the blue light waveband is about 25 nm and the peak FWHM for the red light waveband is about 20 nm. Plants which grow under such kind of light without green waveband form thin and weak leaves without a crispy taste.

### SUMMARY

One objective of the present disclosure is to provide a light source for plant growth and meet the wavelength requirement for chlorophyll a, chlorophyll b, and photomorphogenesis of plants. It will be feasible for plants growing normally in a facility lack of sunlight, such as indoor, basement, container or winter of polar place, and thereby can achieve the stability in harvest.

It mentioned that an ordinary light source for illumination is based upon blackbody radiation, wherein the color of spectrum is usually represented by color temperature. However, the light source for plant growth is not based upon the blackbody radiation, and the color of spectrum is represented by the range of CIE (Commission Internationale de l'Eclairage) coordinates. Accordingly, a light-emitting diode module design for plant growth disclosed in the present disclosure is based upon the spectrum of photosynthesis, wherein the base of measurement uses the range of CIE coordinates to represent the color of light.

To achieve the abovementioned object, the present disclosure provides a light-emitting diode module for plant growth comprising a first light-emitting element and a second light-emitting element. The first light-emitting element is electrically connected to the second light-emitting element. The first light-emitting element emits a first light beam which includes a first blue light and a red light. The wavelength of the first blue light is from 425 nm to 435 nm, and the wavelength of the red light is from 620 nm to 730 nm. The second light-emitting element emits a second light beam which includes a second blue light and a chartreuse light. The wavelength of the second blue light is from 445 nm to 455 nm, and the wavelength of the chartreuse light is from 515 nm to 560 nm.

Accordingly, the CIE coordinates of the first light beam are X values from 0.4 to 0.65 and Y values from 0.15 to 0.38.

Accordingly, the CIE coordinates of the second light beam are X values from 0.1 to 0.32 and Y values from 0.07 to 0.3.

Accordingly, the first light beam and the second light beam mix together to form a composite light beam which has a composite spectrum, and the CIE coordinates of the composite spectrum are X values from 0.25 to 0.5 and Y values from 0.12 to 0.35.

Accordingly, the first light-emitting element includes a first blue light LED chip emitting the first blue light and a first phosphor layer which covers the first blue light LED chip. The first phosphor layer includes red phosphor powder which emits a red light when being stimulated by the first blue light.

Accordingly, the second light-emitting element includes a second blue light LED chip emitting the second blue light and a second phosphor layer which covers the second blue light LED chip. The second phosphor layer includes chartreuse phosphor powder mixture which emits a chartreuse light when being stimulated by the second blue light.

Accordingly, the first phosphor layer further includes a first silicone resin, and the red phosphor powder is dispersed in the first silicone resin. The second phosphor layer further includes a second silicone resin, and the chartreuse phosphor powder mixture is dispersed in the second silicone resin. The first silicone resin and the second silicone resin can are same or different. The red phosphor powder is CaAlSiN₃:Eu or Ca₂Si₅N₈:Eu, and the chartreuse phosphor powder mixture is (BaSr)₂SiO₄:Eu or Lu₃Al₅O₁₂:Ce.

In another implementation of the present disclosure, the light-emitting diode module for plant growth is a light-emitting element. The light emitting element includes a first blue light LED chip which emits the first blue light, a second blue light LED chip which emits the second blue light, and a phosphor layer which covers the first blue light LED chip and the second blue light LED chip. The phosphor layer includes red phosphor powder and chartreuse phosphor powder mixture. The red phosphor powder emits a red light when being stimulated by the first blue light, and the chartreuse phosphor powder mixture emits a chartreuse light when being stimulated by the second blue light. The wavelength of the first blue light is from 425 nm to 435 nm, the wavelength of the second blue light is from 445 nm to 455 nm, the wavelength of the red light is from 620 nm to 730 nm, and the wavelength of the chartreuse light is from 515 nm to 560 nm.

According to the abovementioned technical features, the light-emitting element generates the composite light beam whose CIE coordinates are X values from 0.25 to 0.5 and Y values from 0.12 to 0.35.

According to the abovementioned technical features, the red phosphor powder is CaAlSiN₃:Eu or Ca₂Si₅N₈:Eu, and the chartreuse phosphor powder mixture is (BaSr)₂SiO₄:Eu or Lu₃Al₅O₁₂:Ce.

According to the abovementioned technical features, the phosphor layer includes a silicone resin, and the red phosphor powder and the chartreuse phosphor powder mixture are dispersed in the silicone resin.

According to the present disclosure, the light-emitting diode module for plant growth can overcome many shortcomings resulted from the conventional LED lamp for plants, such as abnormal shape, thin leaves or lack of crispy taste in vegetables. Plants grow under an optimal photosynthesis spectrum can get higher photosynthetic efficiency. Thus, the plants can grow well by controlling the irradiation duration and temperature, and their photomorphogenesis can be regulated, so as to arrange the good timing for harvest for good market.

In order to get further understanding of the technology of the present disclosure, the brief description of the drawings below is followed by the detailed description of the preferred embodiments.

### BRIEF DESCRIPTION OF THE DRAWINGS

FIG. 1 shows a photosynthetic absorbance spectrum of a plant.

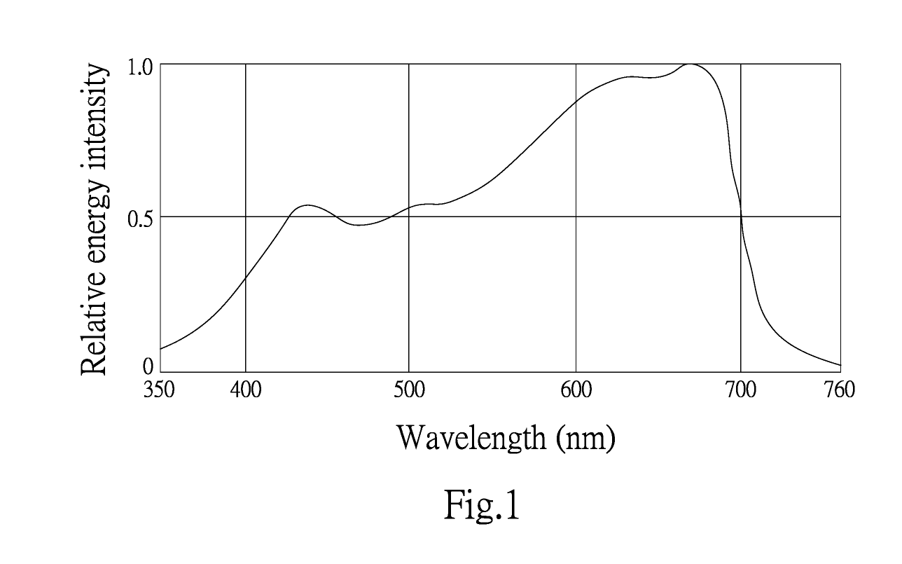

FIG. 2 shows absorbance spectra of chlorophyll a and chlorophyll b of a plant.

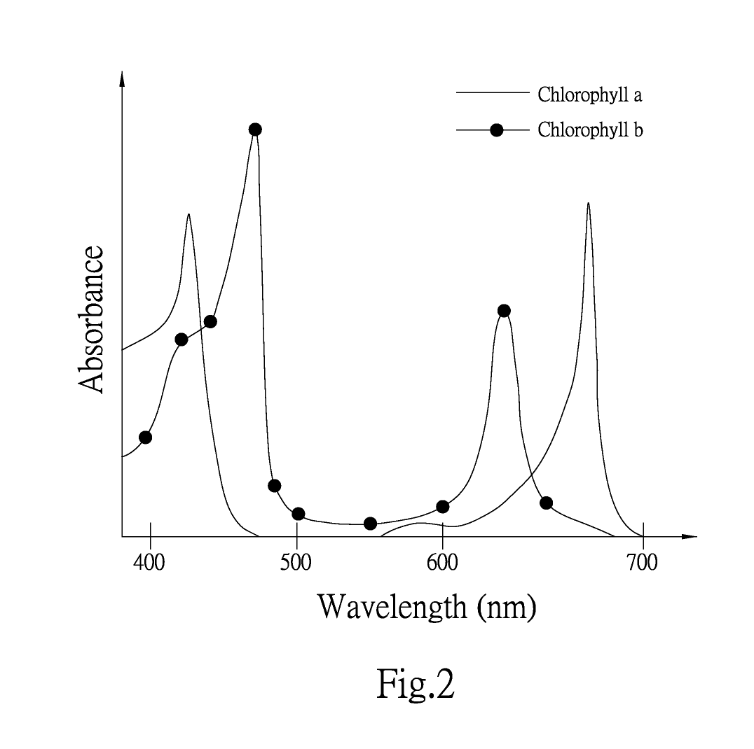

FIG. 3 shows a composite absorbance spectrum of a first kind of artificial light source sold on the current market.

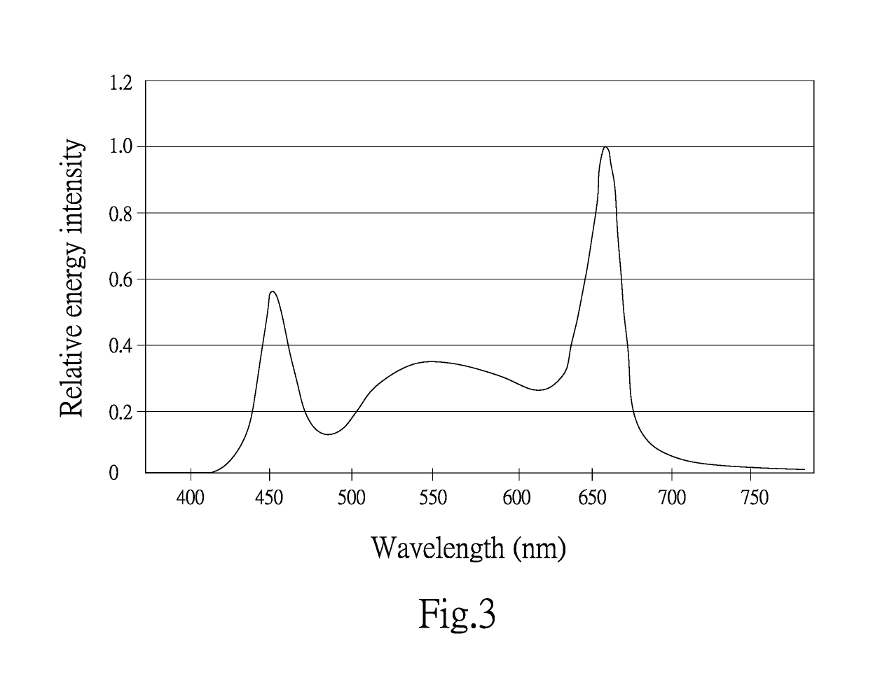

FIG. 4 shows a composite absorbance spectrum of a second kind of artificial light source sold on the current market.

FIG. 5 shows a structural view of a first light-emitting element in the first embodiment of the present disclosure.

FIG. 6 shows a spectrum of a first light beam in the first embodiment of the present disclosure.

FIG. 7 shows a structural view of a second light-emitting element in the first embodiment of the present disclosure.

FIG. 8 shows a spectrum of a second light beam in the first embodiment of the present disclosure.

FIG. 9 shows a composite spectrum of a light-emitting diode module for plant growth in the present disclosure.

FIG. 10 shows a range of CIE coordinates for a composite spectrum of the light-emitting diode module for plant growth in the present disclosure.

FIG. 11 shows structural view of a light-emitting element of a second embodiment in the present disclosure.

### DETAILED DESCRIPTION OF THE EMBODIMENTS

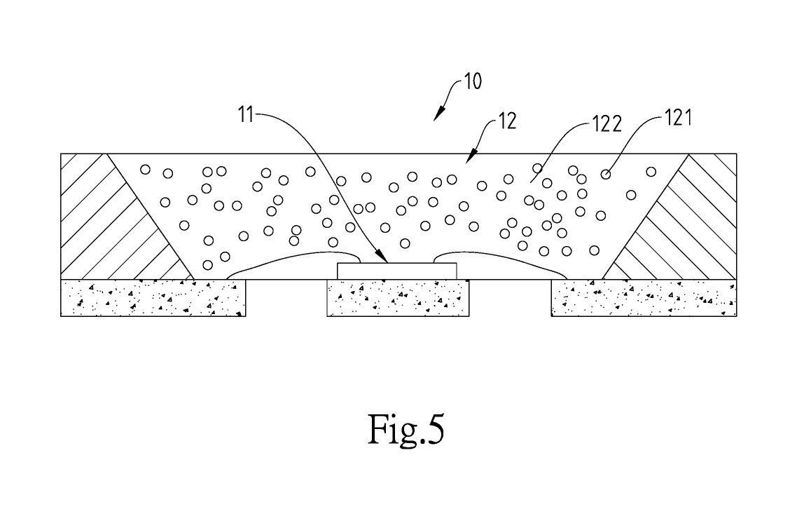

Referring to FIGS. 5 to 10, it shows a first embodiment of a light-emitting diode module for plant growth in the present disclosure. The light-emitting diode module for plant growth comprises a first light-emitting element 10 and a second light-emitting element 20.

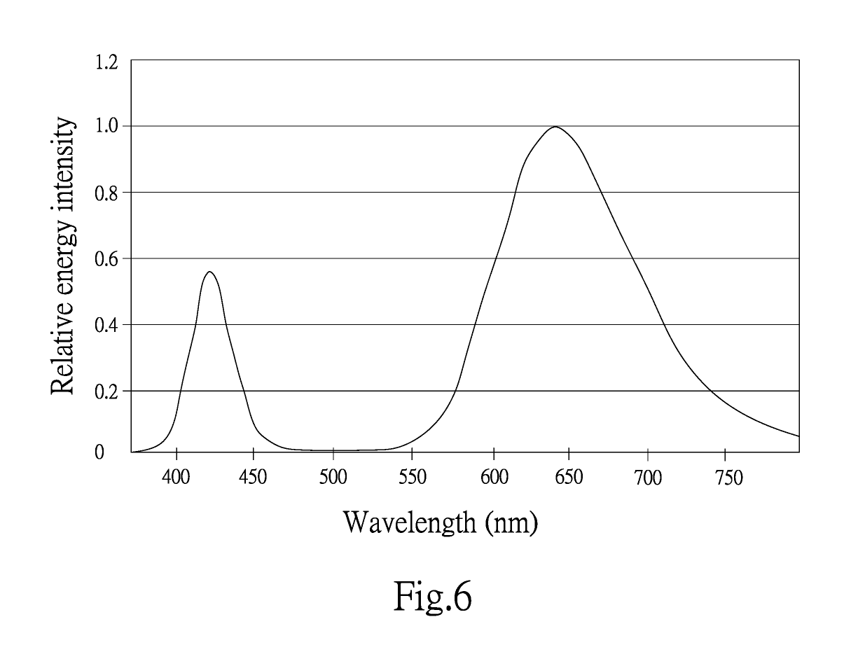

As shown in FIG. 5 and FIG. 6, the first light-emitting element 10 includes a first blue light LED chip 11 which emits a first blue light, and a first phosphor layer 12 which covers the first blue light LED chip 11. The wavelength of the first blue light is from 425 nm to 435 nm, with the preferred wave peak from 425 nm to 435 nm. The first phosphor layer 12 includes red phosphor powder 121 and a first silicone resin 122. The red phosphor powder 121 is the nitride phosphor powder (CaAlSiN₃:Eu or Ca₂Si₅N₈:Eu) and the first phosphor layer 12 is made by mixing the red phosphor powder 121 with the first silicone resin 122, followed by directly coating on the first blue light LED chip 11, which means that the red phosphor powder 121 is dispersed in the first silicone resin 122 to form the first phosphor layer 12. The red phosphor powder 121 in the first phosphor layer 12 emits a red light when being stimulated by the first blue light and the wavelength of the red light is from 620 nm to 730 nm, with the preferred wave peak from 620 nm to 730 nm. The first light-emitting element 10 emits a first light beam which is formed by mixing the first blue light with the red light. The CIE coordinates of the first light beam are X values from 0.4 to 0.65 and Y values from 0.15 to 0.38. Unless otherwise indicated, the numerical ranges involved in the disclosure include the end values.

Therefore, the first blue light (wavelength from 425 nm to 435 nm) of the first light-emitting element 10 is able to meet the wavelength 430 nm which chlorophyll required; the red light (wavelength from 620 nm to 730 nm) of the first light-emitting element 10 is able to meet the wavelength over 700 nm which photomorphogenesis required; the red light also meets the wavelength of 662 nm which chlorophyll a required and the wavelength of 643 nm which chlorophyll b required.

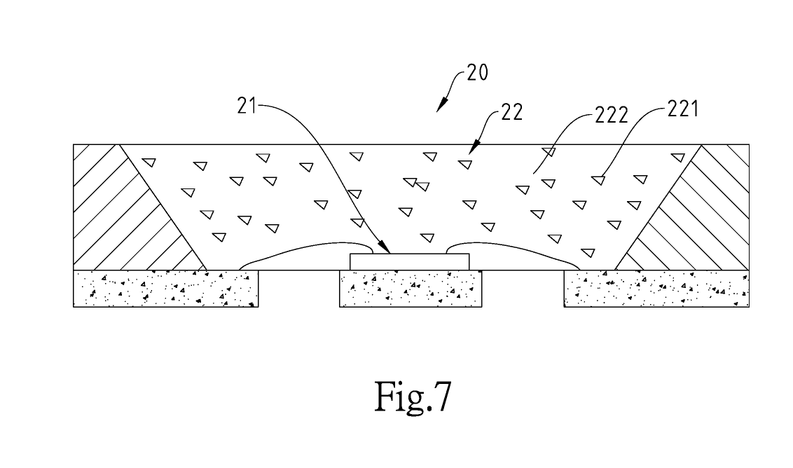

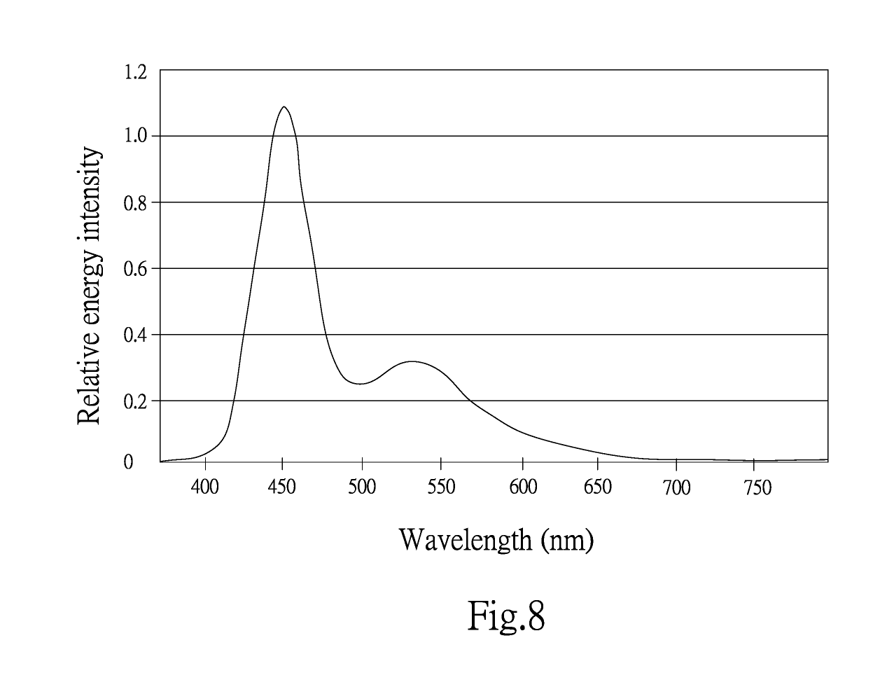

As shown in FIG. 7 and FIG. 8, the second light-emitting element 20 includes a second blue light LED chip 21 which emits a second blue light, and a second phosphor layer 22 which covers the second blue light LED chip 21. The wavelength of the second blue light is from 445 nm to 455 nm, with the preferred wave peak from 445 nm to 455 nm. The second phosphor layer 22 includes chartreuse phosphor powder mixture 221 and a second silicone resin 222. The chartreuse phosphor powder mixture 221 is formed by mixing green phosphor powder with yellow phosphor powder, and it is the silicate powder ((BaSr)₂SiO₄:Eu) or aluminate powder (Lu₃Al₅O₁₂:Ce), wherein the yellow phosphor powder is the silicate powder ((BaSr)₂SiO₄:Eu) or aluminate powder (Lu₃Al₅O₁₂:Ce), and the green phosphor powder is the silicate powder ((BaSr)₂SiO₄:Eu) or aluminate powder (Lu₃Al₅O₁₂:Ce). The second phosphor layer 22 is made by mixing the chartreuse phosphor powder mixture 221 with the second silicone resin 222, followed by directly coating on the second blue light LED chip 21, which means that the chartreuse phosphor powder mixture 221 is dispersed in the second silicone resin 222 to form the second phosphor layer 22. The chartreuse phosphor powder mixture 221 in the second phosphor layer 22 emits a chartreuse light when being stimulated by the second blue light, and the wavelength of the chartreuse light is from 515 nm to 560 nm, with the preferred wave peak from 515 nm to 560 nm. The green phosphor powder emits a green light when being stimulated by the second blue light, and the wavelength of the green light is from 515 nm to 540 nm, with the preferred wave peak from 515 nm to 540 nm. The yellow phosphor powder emits a yellow light when being stimulated by the second blue light, and the wavelength of the yellow light is from 540 nm to 560 nm, with the preferred wave peak from 540 nm to 560 nm. The second light-emitting element 20 is able to emit a second light beam which is formed by mixing the second blue light with the chartreuse light. The CIE coordinates of the second light beam are X values from 0.1 to 0.32 and Y values from 0.07 to 0.3. On the other hand, the first silicone resin 122 and the second silicone resin 222 can be the same or different.

Therefore, the second blue light (wavelength from 445 nm to 455 nm) of the second light-emitting element 20 is able to meet the wavelength of 454 nm which chlorophyll b required; the chartreuse light (wavelength from 515 nm to 560 nm) of the second light-emitting element 20 is able to meet the waveband of chartreuse light (wavelength from 500 nm to 560 nm) which facilitates biosynthesis of carotene. The chartreuse light can penetrate upper-layer leaves to reach the surface of lower-layer leaves, and thereby benefit the photosynthesis of leaves inside canopy layer and increase crispy taste of the plant.

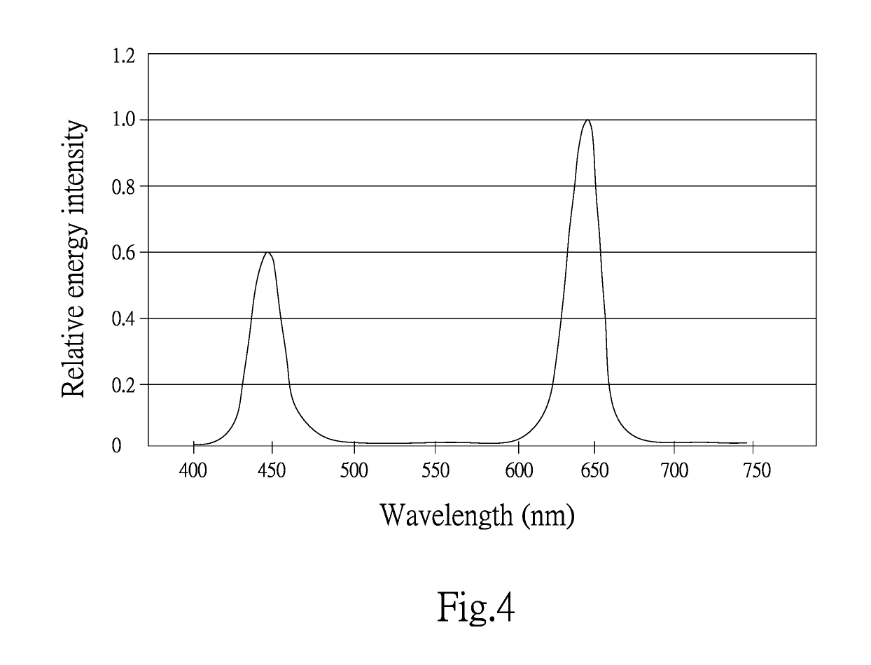

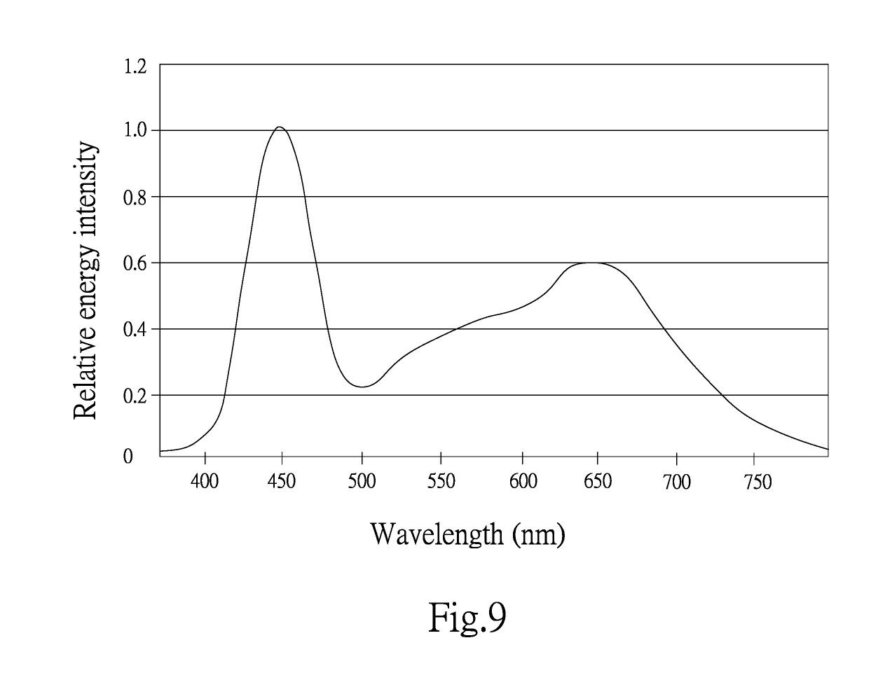

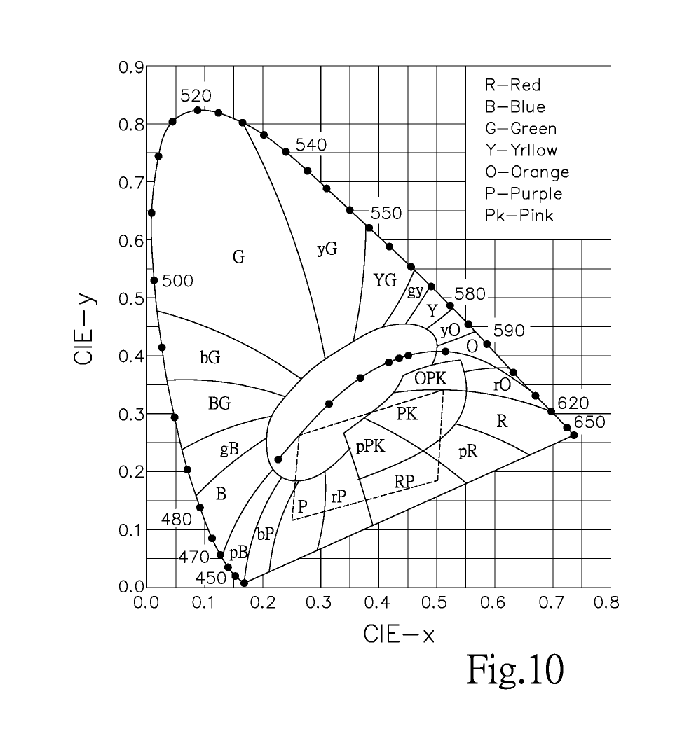

For the light-emitting diode module for plant growth, a spectrum is generated after combining the first light-emitting element with the second light-emitting element, and it means that the first light beam and the second light beam mix together to form the composite light beam which has a composite spectrum. As shown in FIG. 9, the wave peak of the blue light waveband is formed by mixing the first blue light (wavelength from 425 nm to 435 nm) with the second blue light (wavelength from 445 nm to 455 nm). The peak FWHM is about 50 nm, which is apparently wider than the peak FWHM (25 nm) of a single blue light of the second kind of artificial light source in current market abovementioned (as shown in FIG. 4). Therefore, some other essential wavelengths can be included and good for bioreactions of chlorophyll a and chlorophyll b. The CIE coordinates of the composite spectrum are shown in FIG. 10, wherein in the range of a dashed-line rectangular frame, X values are from 0.25 to 0.5, and Y values are from 0.12 to 0.35. That range is the optimal range of CIE coordinates for the photosynthesis spectrum. Furthermore, the first light-emitting element and the second light-emitting element are combined by electric connection, which means that the first light-emitting element is connected electrically with the second light-emitting element.

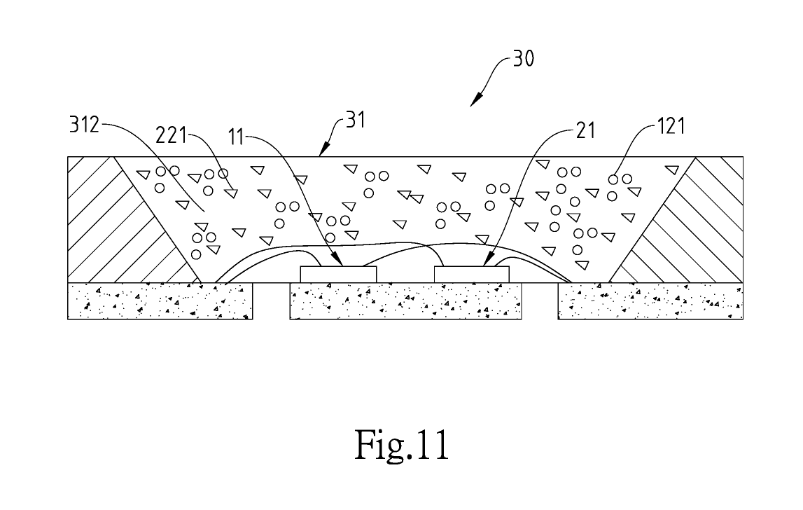

Referring to FIG. 11 and FIG. 9, it shows a second embodiment of the light-emitting diode module for plant growth, according to the present disclosure. The light-emitting diode module for plant growth is a light-emitting element 30 which includes the first blue light LED chip 11 to emit the first blue light, the second blue light LED chip 21 to emit the second blue light, and a phosphor layer 31 to cover the first blue light LED chip 11 and the second blue light LED chip 21. The wavelength of the first blue light is from 425 nm to 435 nm, and the wavelength of the second blue light is from 445 nm to 455 nm. The phosphor layer 31 includes the red phosphor powder 121, the chartreuse phosphor powder mixture 221 and a silicone resin 312. The red phosphor powder 121 is the nitride phosphor powder (CaAlSiN₃:Eu or Ca₂Si₅N₈:Eu), the chartreuse phosphor powder mixture 221 is the silicate phosphor powder ((BaSr)₂SiO₄:Eu) or aluminate phosphor powder (Lu₃Al₅O₁₂:Ce). The phosphor layer 31 is made by mixing the red phosphor powder 121, the chartreuse phosphor powder mixture 221 and the silicone resin 312, followed by directly coating on the first blue light LED chip 11 and the second blue light LED chip 21, which means that the red phosphor powder 121 and the chartreuse phosphor powder mixture 221 are dispersed in the silicone resin 312 to form the phosphor layer 31. The phosphor layer 31 is able to emit the red light when being stimulated by the first blue light, and the wavelength of the red light is from 620 nm to 730 nm. In addition, the phosphor layer 31 is able to emit the chartreuse light when being stimulated by the second blue light LED chip, and the wavelength of the chartreuse light is from 515 nm to 560 nm. In the present embodiment, the light-emitting element 30 of the light-emitting diode module for plant growth is able to generate a spectrum, as shown in FIG. 9. The wave peak in the blue light waveband is formed by mixing the first blue light (wavelength from 425 nm to 435 nm) with the second blue light (wavelength from 445 nm to 455 nm), and the peak FWHM is about 50 nm, which is apparently wider than the peak FWHM (25 nm) of a single blue light in the second kind of artificial light source in the current market abovementioned (as shown in FIG. 4). Therefore, some other essential wavelengths can be included and good for chlorophyll a and chlorophyll b bioreactions. Most preferably, the wave peak of the first blue light is from 425 nm to 435 nm, the wave peak of the second blue light is from 445 nm to 455 nm, the wave peak of the chartreuse light is from 515 nm to 560 nm, the wave peak of the red light is from 620 nm to 730 nm, the wave peak of the green light is from 515 nm to 540 nm, and the wave peak of the yellow light is from 540 nm to 560 nm. The CIE coordinates of the composite spectrum are X values from 0.25 to 0.5 and Y values from 0.12 to 0.35; that range is an optimal range of CIE coordinates for the photosynthesis spectrum.

In the abovementioned embodiment, the R:G:B PPFD (Photosynthetic Photon Flux Density) ratio of the composite spectrum (R represents the red light, G represents the green light, and B represents the blue light) is different from each stage of plant growth. It can be shown as A:B:C, wherein A is from 0.7 to 4.9, B is from 0.5 to 2.1, and C is 1. In the present embodiment, R:G:B PPFD ratio 1.4:1.3:1 is used on seedling stage. Until seedlings form at least two leaves, they are transplanted to a hydroponic bed with hydroponic nutrient solution. The R:G:B PPFD ratio 4.9:2.1:1 is used on the hydroponic cultivation stage. Plants are harvested 4 weeks after the transplant to a hydroponic bed. The R:G:B PPFD ratio 0.7:0.5:1 is used three days before harvesting. Only artificial light source is used for plant growth. The temperature of the cultivation environment is from 20° C. to 25° C., the distance from the light source for plant growth to the culture shelf of plant is 35 cm, the average light intensity is 250 μmolm⁻²s⁻¹, and the photoperiod is 12 hours.

Many experimental tests show that plants grow under the present disclosure observed no abnormal in shape or color of leaves when harvest. They are similar to those plants grow by ordinary growing method. Furthermore, the freshness and the crispy taste of plants cultivated by the present disclosure are superior to the plant cultivated by the first kind of artificial light source used in current market.

This disclosure exhibits the innovative, progressive and practical applications. Thus this disclosure claimed. The embodiments described here are only a few examples. The claims are not limited to these examples. They are the principles of the innovation of this disclosure.

What is claimed is:

1. A light-emitting diode module for plant growth, comprising:
a first light-emitting element and a second light-emitting element;
wherein the first light-emitting element is electrically connected to the second light-emitting element; the first light-emitting element emits a first light beam which includes a first blue light and a red light;
the wavelength of the first blue light is from 425 nm to 435 nm, the wavelength of the red light is from 620 nm to 730 nm; the second light-emitting element emits a second light beam which includes a second blue light and a chartreuse light; the wavelength of the second blue light is from 445 nm to 455 nm, and the wavelength of the chartreuse light is from 515 nm to 560 nm.

2. The light-emitting diode module for plant growth according to claim 1, wherein the CIE coordinates of the first light beam are X values from 0.4 to 0.65 and Y values from 0.15 to 0.38.

3. The light-emitting diode module for plant growth according to claim 1, wherein the CIE coordinates of the second light beam are X values from 0.1 to 0.32 and Y values from 0.07 to 0.3.

4. The light-emitting diode module for plant growth according to claim 1, wherein the first light beam and the second light beam mix together and form a composite light beam has a composite spectrum; the CIE coordinates of the composite spectrum are X values from 0.25 to 0.5 and Y values from 0.12 to 0.35.

5. The light-emitting diode module for plant growth according to claim 4, wherein the CIE coordinates of the first light beam are X values from 0.4 to 0.65 and Y values from 0.15 to 0.38; the CIE coordinates of the second light beam are X values from 0.1 to 0.32 and Y values from 0.07 to 0.3.

6. The light-emitting diode module for plant growth according to claim 4, wherein the R:G:B PPFD ratio of the composite light beam is shown as A:B:C, where A is from 0.7 to 4.9, B is from 0.5 to 2.1, and C is 1.

7. The light-emitting diode module for plant growth according to claim 1, wherein the first light-emitting element includes a first blue light LED chip which emits the first blue light and a first phosphor layer which covers the first blue light LED chip; the first phosphor layer containing red phosphor powder, emits the red light when being stimulated by the first blue light.

8. The light-emitting diode module for plant growth according to claim 1, wherein the second light-emitting element includes a second blue light LED chip which emits the second blue light and a second phosphor layer which covers the second blue light LED chip; the second phosphor layer containing chartreuse phosphor powder mixture, emits the chartreuse light when being stimulated by the second blue light.

9. The light-emitting diode module for plant growth according to claim 8, wherein the first light-emitting element includes: a first blue light LED chip which emits the first blue light and a first phosphor layer which covers the first blue light LED chip; the first phosphor layer containing red phosphor powder which emits the red light when being stimulated by the first blue light.

10. The light-emitting diode module for plant growth according to claim 9, wherein the CIE coordinates of the first light beam are X values from 0.4 to 0.65 and Y values from 0.15 to 0.38; the CIE coordinates of the second light beam are X values from 0.1 to 0.32, and Y values from 0.07 to 0.3.

11. The light-emitting diode module for plant growth according to claim 10, wherein the first phosphor layer includes a first silicone resin, the red phosphor powder is dispersed in the first silicone resin; the second phosphor layer includes a second silicone resin, the chartreuse phosphor powder mixture is dispersed in the second silicone resin; the first silicone resin and the second silicone resin are the same or different; the red phosphor powder is CaAlSiN₃:Eu or Ca₂Si₅N₈:Eu; the chartreuse phosphor powder mixture is (BaSr)₂SiO₄:Eu or Lu₃Al₅O₁₂:Ce.

12. The light-emitting diode module for plant growth according to claim 11, wherein the chartreuse phosphor powder mixture includes green phosphor powder and yellow phosphor powder, the green phosphor powder emits a green light after being stimulated by the second blue light, the wavelength of the green light is from 515 nm to 540 nm, the yellow phosphor powder emits a yellow light after being stimulated by the second blue light, and the wavelength of the yellow light is from 540 nm to 560 nm.
